(19) United States
(12) Patent Application Publication
(10) Pub. No.: US 2008/0268615 A1
(43) Pub. Date: Oct. 30, 2008

(54) Treatment of a Germanium Layer Bonded with a Substrate

(76) Inventors: Frederic Allibert, Grenoble (FR); Chrystel Deguet, Saint Ismier (FR); Claire Richtarch, Grenoble (FR)

Correspondence Address: WINSTON & STRAWN LLP;PATENT DEPARTMENT, 1700 K STREET, N.W., WASHINGTON, DC, 20006, US

(21) Appl. No.: 12/090,318

(22) PCT Filed: Oct. 17, 2006
(86) PCT No.: PCT/FR2006/002332

§ 371 Date: Apr. 15, 2008

(30) Foreign Application Priority Data
Oct. 19, 2005 (FR) 0510636

(51) Int. Cl. H01L 21/46

(52) U.S. Cl. 438/455; 257/E21.122

(57) ABSTRACT

The invention relates to a treatment method of a structure comprising a thin Ge layer on a substrate, said layer having been previously bonded with the substrate, the method comprising a treatment to improve the electrical properties of the layer and/or the interface of the Ge layer with the underlying layer, characterised in that said treatment is a heat treatment applied at a temperature between 500° C. and 600° C. for not more than 3 hours.

The invention also relates to a method to produce a structure comprising a Ge layer, the method comprising bonding between a donor substrate comprising at least in the upper part thereof a thin Ge layer and a receiving substrate, characterised in that it comprises the following steps:
(a) bonding of the donor with the receiving substrate such that the Ge layer is located in proximity to the bonding interface;
(b) removal of the part of the donor substrate not comprising the Ge layer;
(c) treatment of the structure comprising the receiving substrate and the Ge layer in accordance with said treatment method.

The invention relates to the production and treatment of a structure comprising a layer of Germanium on a substrate, such as a Germanium-On-Insulator structure (also referred to as a “GeOI” structure), intended for applications in microelectronics (MOS production for example) and/or in optoelectronics (photodetectors for example) and/or photovoltaic applications (solar cells for example). Such a GeOI structure comprises said Ge layer on a layer of electrical insulator on a substrate.

Germanium has more beneficial electrical characteristics than those of silicon, among other things due to a greater mobility of the charges within said material (theoretical hole mobility of 1900 cm²V⁻¹s⁻¹, electron mobility 3900 cm²V⁻¹s⁻¹).

It is desirable to be able to produce such a Ge layer having a good crystalline, electrical and morphological quality on the entire surface of the layer according to the future applications, in order to be able subsequently to form transistors or integrated detectors thereon, for example.

The documents U.S. Pat. No. 6,833,195 and US 2005/0042842 each disclose a GeOI structure production method, comprising the epitaxy of a layer of Ge on a first substrate, the formation of an SiO₂ film on the epitaxied Ge layer, ion implantation under the Ge layer in order to create a weakening zone thereon, bonding with a second substrate, followed by a detachment of the Ge layer on the weakening zone, to finally obtain a GeOI structure (this detachment technique is also known using the term “Smart Cut®”).

The method according to these documents also discloses a reinforcement of the bonding (i.e. a densification of the bonding layer) by means of heat treatment before detachment at temperatures of 100-150° C. for 1 to 60 hours, and a final Ge surface finishing step using polishing, a wet chemical treatment, or etching, to rectify inhomogeneities and surface roughness.

A first general problem encountered with germanium is its high reactivity with oxygen, resulting in the creation of a Germanium oxide layer which has an adverse effect on the electrical properties of the Ge layer.

This oxidation may in particular occur at the Ge/SIO₂ interface.

From the document EP 04 292742 (filing No.), it is known how to form, before the formation of the SiO₂ layer, a GeOxNy passivation layer possibly followed by the formation of an interfacial layer, making it possible to prevent oxidation of the Ge layer and obtain an improved interface quality with SiO₂.

In addition, in multi-layer structures comprising a deposited oxide, an SIO₂ densification step is frequently required. In the case of a TEOS type oxide, the oxide densification step is generally performed at approximately 900° C. for transferred Si layers, and may only be produced partially for the transferred Ge layer (or for times incompatible with industrial production requirements).

In the document US 2005/0148122, however, a densification at 600° C. for one hour is proposed.

It is also known to prepare the Ge surface before the dielectric deposition, according to various techniques. For example, it is possible to deposit a thin layer of Silicon just before carrying out the formation of the dielectric layer (see for example, for more details on techniques used to this end, the following documents, incorporated as a reference: “Si interlayer passivation on germanium MOS capacitors with high-k dielectric and metal gate” by Bai et al. —Elec. Dev; 26(6) 378-380 (2005)—; and “Optimisation of a thin epitaxial Si layer as Ge passivation layer to demonstrate deep sub-micron n- and p-FETs on Ge-On-Insulator substrates” by Jaeger et al. —Micro. Engin; 80 26-29 (2005).

A second problem encountered in heterostructures with a transferred Ge layer, for example by means of Smart Cut®, is the need to carry out the transfer at limited temperatures, germanium oxide becoming very volatile very quickly (instability of oxidised form thereof) and the melting point thereof being relatively low (937° C.). The temperatures used are thus rapidly limited.

Moreover, in the case of germanium, the thickness damaged following Smart Cut® ion implantation is much greater than in the case of silicon. For this reason, a heat treatment enabling crystalline reconstruction (restoration of residual implantation defects) would be desirable.

Therefore, it can be stated that, in order to obtain a good quality of the thin Ge film transferred by means of Smart Cut®, it is essential to carry out these heat treatments correctly particularly at temperature ranges compatible with germanium.

One aim of the invention is to obtain a structure comprising a superior Ge layer and an interface with a base substrate both having a good crystalline and morphological quality.

Another aim of the invention is to improve the electrical properties of the Ge layer.

Another aim of the invention is to optimise the electrical quality of the GeOI substrate at the Ge/insulator interface.

In particular, if the Ge layer was initially taken from a donor substrate, one aim is to preserve the good quality electrical, morphological and/or crystalline characteristics for the Ge layer, for applications in microelectronics (MOS production for example), optoelectronics, and/or photovoltaics, etc.

To achieve these aims, the invention proposes, according to a first aspect, a treatment method of a structure comprising a thin Ge layer on a substrate, said layer having been previously bonded with the substrate, The method comprises a treatment to improve the electrical properties of the layer and/or the interface of the Ge layer with the underlying layer, characterised in that said treatment is a heat treatment applied at a temperature between 500° C. and 600° C. for not more than 3 hours, or more specifically between 525° C. and 575° C., or more specifically between 525° C. and 550° C., or more specifically at a temperature of approximately 550° C. The heat treatment may also more specifically lasts for approximately 1 hour and/or be carried out in an inert atmosphere. The thin layer transferred may have an approximate thickness of less than 1.5 micrometres, preferentially between approximately 50 and approximately 200 nanometres, and/or the substrate may be made of silicon.

Optionally, the Ge layer is the upper layer of the structure, and said upper layer is bonded directly or solely by means of a bonding layer.

Advantageously, the structure is a GeOI structure, i.e. it also comprises a layer of electrical insulating material between the thin layer and the substrate. The insulator layer may be an oxide, a nitride or an oxynitride or consist of a juxtaposition of different layers of different types.

In fact, in particular in such GeOI structures, the inventors demonstrated (see below) that the use of such a heat treatment according to the invention enables not only the substantial restoration of the Ge layer from existing defects, but also increases the electrical quality of the layer and/or the Ge/insulator interface, particularly by achieving acceptable “Density of Interface Trap” (or “Dit”) values. Therefore, a basic heat treatment may suffice to increase the electrical and/or optical quality of a Ge interface, without systematically having to provide a passivation layer and/or an interfacial layer as disclosed in EP 04292742 (filing No.).

However, in any case, it may be possible to optionally provide for the structure to comprise a passivation layer adjacent to the thin layer and/or an interfacial layer between the thin layer and the rest of the structure, the interfacial layer being made of a material making it possible to improve the electrical and/or optical properties at the interface with Ge.

According to a second aspect, the invention proposes a method to produce a structure comprising a Ge layer, the method comprising bonding between a donor substrate comprising at least in the upper part thereof a thin Ge layer and a receiving substrate, characterised in that it comprises the following steps:

(a) bonding of the donor with the receiving substrate such that the Ge layer is located in proximity to the bonding interface;

(b) removal of the part of the donor substrate not comprising said Ge layer;

(c) treatment of the structure comprising the receiving substrate and the Ge layer in accordance with said treatment method.

The donor substrate may be a bulk Ge substrate or a composite structure comprising said epitaxied Ge layer on the surface.

The receiving substrate may be made of any type of material (it may for example comprise bulk Si, SiC, SiGe, SiGeC, Ge, GeC, quartz, glass, III-V or II-VI alloy materials, etc.).

Other characteristics of this method to produce a structure are:
the method also comprises, before step (a), the formation of a passivation layer on said Ge layer; the passivation layer may be made of GeOxNy, formed among other things according to any of the following techniques:

surface Ge oxidation followed by nitriding of the Ge oxide;

heat treatment;

plasma treatment by means of the precursor NH₃, N₂, O₂ or a mixture of N2+O₂.
the method also comprises, before step (a), the deposition of an interfacial layer on said Ge layer (or on the passivation layer if applicable), with a material intended to improve the electrical and/or optical properties at the interface with Ge, such as epitaxied Si, a high dielectric constant (“high-k”) material, HfO₂, AlN;
the method also comprises, before step (a), the formation step of a layer of electrical insulator on the donor substrate and/or on the receiving substrate, consisting at least essentially of a material such as an oxide, SiO₂, HfO₂, SrTiO₃, Ta₂O₅, TiO₂, ZrO₂, Al₂O₃, or Y₂O₃, or a nitride or an oxynitride, for example of Al, Ge or Si;
in the above case where the insulating layer is made of SiO₂, it is formed by means of one of the following techniques: PECVD deposition for example using silane or using TEOS, thermal oxidation of a layer of Si previously deposited on the Ge layer and/or of the Si surface of the receiving substrate;
the formation of the insulating layer is applied at a temperature of approximately 500° C. or less, and optionally a densification step of the insulating layer is applied by means of heat treatment below 600° C.;
said step (b) of the method is applied using any of the following techniques, alone or in combination: polishing, grinding, etching;
as an alternative embodiment: the method also comprises:

before step (a), an atomic species implantation step in the donor substrate in order to form a weakening zone at a depth similar to the thickness of said Ge layer;

step (b) comprises an energy supply to break the weak bonds present on the weakening zone;
the method also comprises, after step (b), a finishing step of the Ge layer so as to improve the thickness homogeneity and surface roughness thereof, the latter may thus be between approximately 1 and approximately 5 Angstroms RMS.

According to a third aspect, the invention proposes a Ge-on-insulator structure comprising a Ge layer bonded with a substrate via an SiO₂ bonding layer having a density of Ge/SiO₂ interface traps (or “Dit”) less than or equal to 5e¹³ eV⁻¹. cm⁻², or less than or equal to 1e¹³ eV⁻¹. cm² or approximately equal to 7e¹² eV⁻¹ cm⁻². Optionally, the structure also comprises a passivation and/or interface layer between the Ge layer and the SiO₂ layer.

Other characteristics, aims and advantages will be described in the non-limitative description of the invention which follows, illustrated by the following figures:

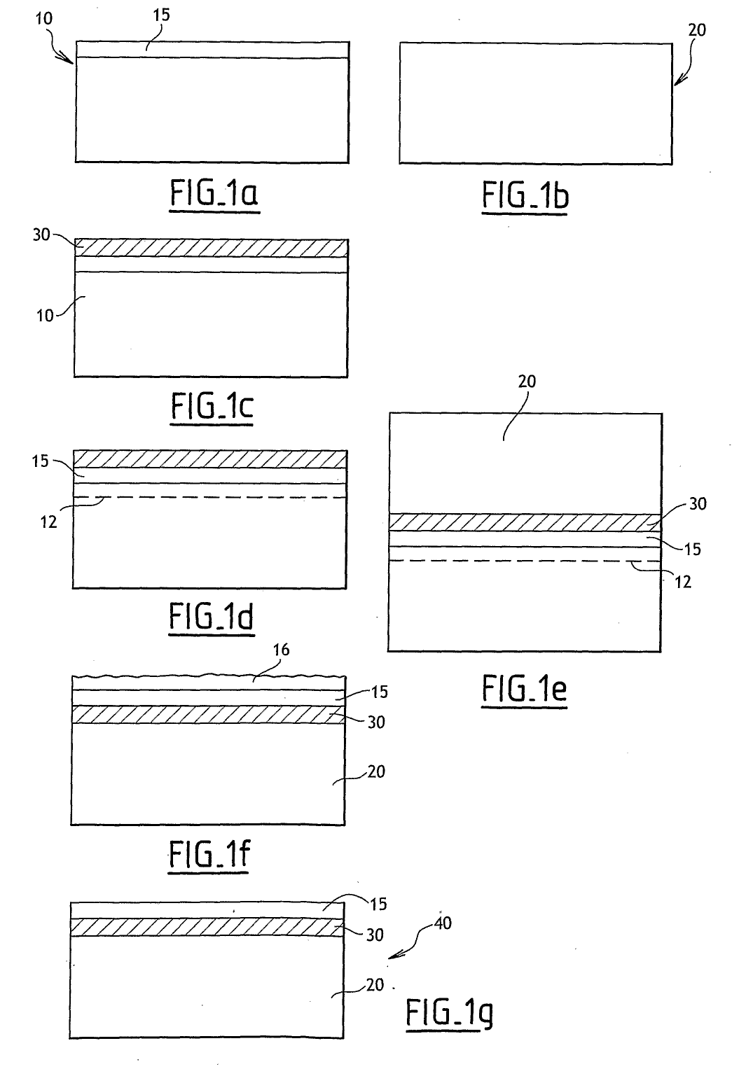

FIGS. 1a to 1g represent different steps of a GeOI structure formation method according to the invention.

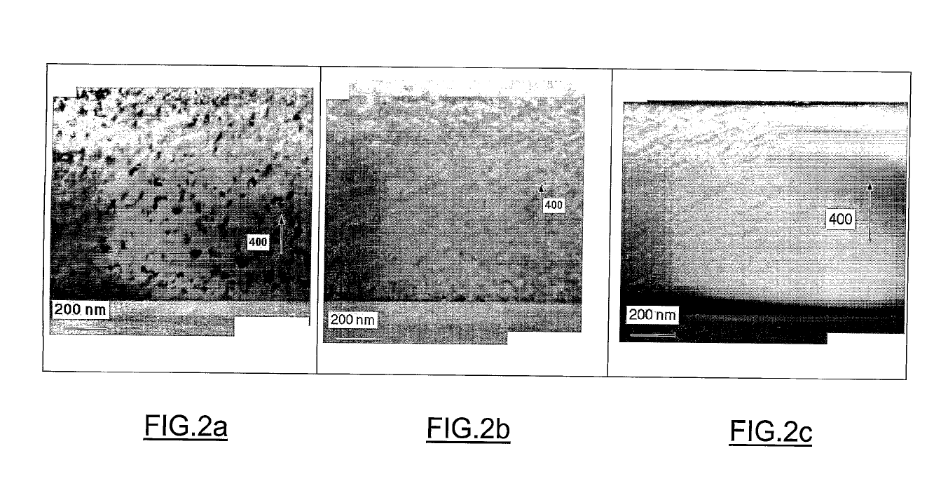

FIGS. 2a to 2c represent, respectively three photos taken by means of scanning electron microscopy of three layers of germanium transferred onto insulator, after heat treatments at respective temperatures of 500° C., 550° C. and 600° C.

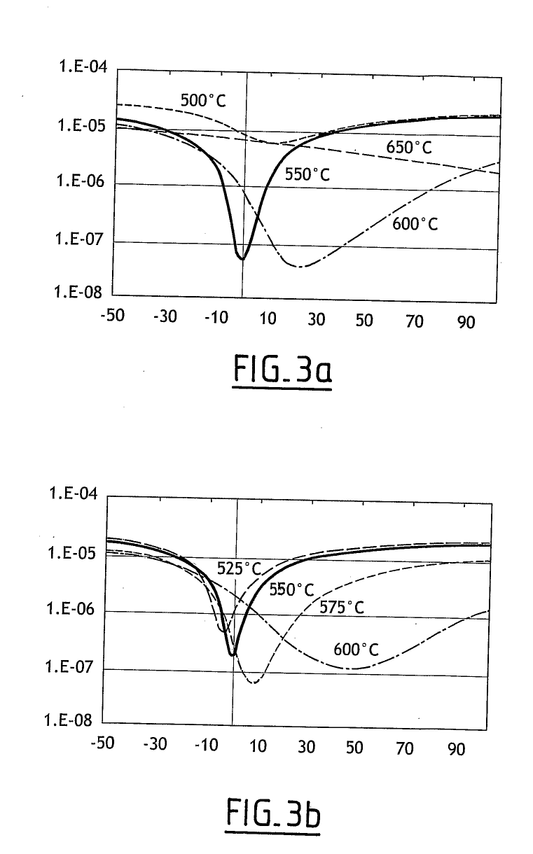

FIGS. 3a and 3b are two representative diagrams of drain-source currents (in Amperes) measured on GeOI structures, as a function of the voltage (in Volts) applied to the base substrate, during a Pseudo-MOS type test—each curve being obtained for a different GeOI structure annealing temperature.

The method to produce a thin layer of germanium on insulator comprises different steps which will be described specifically below.

With reference to FIG. 1, the donor substrate 10 may be a bulk Ge substrate, the germanium layer 15 thus being included in the bulk material.

According to a first alternative, the donor substrate 10 is a silicon substrate coated with an epitaxied Ge layer 15.

According to a second alternative, the donor substrate 10 is a composite structure coated with an epitaxied Ge layer 15.

In the latter case, the donor substrate 10 may for example be a structure having a bulk monocrystalline silicon substrate whereon a buffer structure, comprising successive SiGe layers having progressively increasing Ge concentrations moving away from the substrate, has been formed by means of epitaxy, up to the Ge layer.

The donor substrate 10 may also have, for example, Si/Ge/Si/Ge alternations.

With reference to FIG. 1b, a receiving substrate 20 is represented, intended to be subsequently bonded with the donor substrate 10. It may consist of any type of material (it may for example comprise bulk Si, Silicon oxide, SiC, SiGe, SiGeC, Ge, GeC, quartz, glass, III-V or II-VI alloy materials, etc.).

With reference to FIG. 1c, a layer of an electrically insulating material 30 is deposited on the donor substrate 10 and/or on the receiving substrate 20.

A specific preparation of the germanium may be applied before the deposition of the insulating layer 30.

The surface may thus be cleaned with, for example, an HF and/or ozone solution possibly followed by brushing.

Optionally, and prior to the deposition of the insulating layer 30, a passivation of the layer 15 may be carried out to improve the quality of the interface between the germanium and the insulator with which the layer 15 will be in contact. This passivation may possibly have an “adhesion layer” function with any material subsequently deposited. For example, this passivation may be a formation of a thin GeOₓN_{y} layer on the surface of the layer 15, so that the Ge is stable in air, and in order to improve the interface qualities. This layer is for example formed according to the following different techniques, alone or in combination:
surface oxidation of Ge followed by nitriding of Ge oxide, or vice versa;
heat treatment using precursors for nitrogen, such as NH₃ or N₂, and precursors for oxygen, such as water or dioxygen. The heat treatments may be conventional treatments, more or less long treatments as a function of the thickness involved, but also RTO (or “Rapid Thermal Oxidation”) or RTN (or “Rapid Thermal Nitridation”) treatments;
plasma treatment by means of the precursor NH₃, N₂, O₂ or a mixture of N₂+O₂.

A so-called “interfacial” layer, of another type, may also and optionally be deposited, directly or via the passivation layer, on the germanium layer 15, before the insulating layer 30.

The nature and arrangement of said interfacial layer are selected so as to make it possible to improve the quality of the Ge/insulator interface from an electrical, optical, mechanical or other point of view depending on the intended final application. It may be thin or thick, and consist for example of epitaxied Silicon, or a high dielectric constant layer (“High-k” layer), an HfO₂ layer or an AlN layer.

Its thickness may thus typically vary from a few A to a few hundred Å.

This layer may be formed before or after the implantation step (see FIG. 1d).

The preparation of the surface of the layer 15 may also be a layer wherein the composition would be a combination of a material which would be used for a passivation layer and a material which would be used for an interfacial layer.

The insulating layer 30 is formed on the donor substrate 10 and/or on the receiving substrate 20.

If the insulating layer 30 is formed on the receiving substrate 20, in principle there are no temperature limits. This is particularly the case if said substrate is made of silicon, or another material more resistant to high temperatures. In this way, for example, if the receiving substrate 20 has at least the upper part thereof made of silicon, an insulating layer made of thermal oxide may be formed, at temperatures typically exceeding 1000° C.

On the other hand, if said insulating layer 30 is produced on the donor substrate 10, it is advantageously formed at low temperatures (less than or equal to approximately 600° C., or less than or equal to approximately 500° C.) due to the physical characteristics of Ge discussed above.

It would be possible for example to have silicon oxide layers deposited, for example in vapour phase, with SiH₄ and TEOS (tetra-ethyl-ortho-silicate), but also to form layers of different types, i.e. SiO₂, HfO₂, SrTiO₃, Ta₂O₅, TiO₂, ZrO₂, Al₂O₃, Y₂O₃.

The insulating layer 30 may also be a layer of nitride or oxynitride of Al, Ge, Si, or other elements.

These layers may be deposited on germanium for example by means of LPCVD (Low Pressure Chemical Vapour Deposition) or by means of PECVD (Plasma Enhanced Chemical Vapour Deposition).

The insulating layer 30 deposited in this way is then advantageously subjected to a densification, making it possible to fix it.

The densification temperature is a critical temperature as it is limiting. In fact, all the future steps of the method should not significantly exceed this densification temperature in order to prevent the structure from changing: a step at a higher temperature could cause the creation of further stress in the layer, or further densification of the layer, or if applicable degassing of said layer. Therefore, said densification temperature should be taken into account for the remainder of the method.

For example, for a TEOS layer deposited on germanium, the deposition temperatures vary from 300° C. to 400° C. The densification following the TEOS deposition will take place by heating the structure to approximately 600° C. maximum in inert gas (Ar, N₂).

The densification temperature will be limited by the unstable nature of the underlying Ge. In this way, this temperature will be limited to approximately 600° C.

A Ge interface restoration heat treatment may also be carried out, before the deposition of the insulating layer, before the bonding with the receiving substrate or after the implantation step. This treatment will make it possible to improve the quality of the layer itself but above all improve the quality of the interface between the interfacial layer and the insulating layer.

Cleaning and passivation and/or formation of an interfacial layer may also be envisaged at this stage of the method.

With reference to FIG. 1d, an atomic species implantation is carried out via one face of the donor substrate 10 in order to create a weakening zone 12 in or under the germanium layer 15, preferentially within the Germanium layer. The implanted species are generally selected as being light, like hydrogen, or helium. Co-implantation may also be carried out by implanting at least two different species.

For example, in the case of a basic hydrogen implementation, the doses applied may vary from 4e16 at/cm² to 7e16 at/cm². In terms of energy, it may vary from 40 keV to 250 keV as a function of the thickness of germanium to be transferred (between approximately 1000 Å and 1.5 μm) according to the Smart Cut® method.

In the case of a co-implantation, whether for a layer of epitaxied germanium or present in a bulk material, it will be possible to use for example hydrogen or helium. The doses used may vary from 7e16 at/cm² to 2e16 at/cm² for hydrogen and from 3e16 at/cm² to 0.5e16 at/cm² for helium. In terms of ion energy, it may vary from 40 to 250 keV, preferentially from 70 to 90 keV for hydrogen and from 60 to 250 keV, preferentially from 120 to 140 keV for helium.

If the layer 15 is not coated with an insulating layer 30 or a thin insulating layer 30, a protective layer (not illustrated in FIG. 1d) of the layer 15 is preferentially formed. The protective layer is arranged to be able to easily removable, in a selective manner, with respect to the layer whereon it rests. It will be possible to use for example an SiO₂ protective layer on an HfO₂ insulating layer to produce same. Said protective layer may then be removed after the implantation.

With reference to FIG. 1e, the donor substrate 10 is bonded with the receiving substrate 20 via the insulating layer 30. The insulating layer 30 may also act as a bonding layer. This is particularly the case if an insulating layer 30 made of SiO₂ is used.

Various possible types of cleaning may then be used, according to the presence or absence of the insulating layer 30 and/or the interfacial layer. The types of cleaning cited as examples below are generally carried out in liquid phase with or without brushing, and with or without O₃:

1—Cleaning of the germanium (on donor substrate) HF and/or HF/O₃ and/or plasma and/or UV ozone.

2—Cleaning of the insulator (on receiving and/or donor substrate): CMP and/or plasma and/or RCA, water, NH₄OH.

3—Cleaning of the silicon (on receiving substrate): RCA, water, ammonia.

The cleanings of the insulating layer 30 or the substrates may be carried out on wet benches, or one single-wafer cleaning machines with adaptable chemistry, by means of liquid chemistry.

One or more surface preparation treatments with a view to molecular bonding may also be used, such as chemical cleaning, chemical mechanical planarisation (or CMP), plasma activation, or brushing, or a combination of these treatments. Plasma activation may be particularly suitable for the situation as it enables satisfactory bonding without necessarily using high bonding temperatures. Such a plasma treatment may be performed on the receiving substrate 20 before or after cleaning.

The bonding is performed between the donor substrate 10 and the receiving substrate 2. Various scenarios are involved:
so-called “bottom” bonding if the donor substrate 10 has an insulating layer 30 but not the receiving substrate 20;
so-called “middle” bonding if the donor 10 and receiving 20 substrates each have an insulating layer 30;
so-called “top” bonding if the donor substrate 10 has no insulating layer 30 but the receiving substrate 20 has one.
direct bonding if neither of the substrates 10 and 20 have an insulating layer 30.

The bonding may be performed at ambient temperature, the bonding times varying in this case typically from 3 to a few seconds.

Optionally, the bonding interface may be reinforced at temperatures less than the detachment temperature, i.e. less than 300° C. (for a conventional hydrogen implantation).

With reference to FIG. 1g, the layer 15 is detached from the donor substrate 10, supplying sufficient energy to break the weak bonds on the weakening zone 12.

The detachment temperature range is closely linked with the implantation conditions used (dose, energy, type of ions implanted, etc.).

The transfer may be carried out by means of heat treatment (advantageously if the layer 15 is an initially epitaxied layer) or by means of a heat treatment coupled with a mechanical opening (advantageously if the layer 15 is a layer initially comprised in a bulk donor substrate 10).

For example, the temperatures used for the detachment may vary from 250° C. to 380° C. for a time from 15 min to 3 hrs, more specifically 30 min and 1 hr, with a gradient of 5 to 10° C./min.

The temperature and the conditions (gradient, atmosphere) may be adapted according to the implantation conditions and the nature of the materials to obtain a detachment time compatible with industrial use.

After detachment, a damaged zone 16 remains on the top part of the layer 15.

Different chemical removal techniques of this damaged part may be envisaged, depending on the chemical means used. Polishing alone or combined with chemical etching may also be performed. In any case, a final CMP step is advantageously used in order to reduce the final roughness of the layer 15.

For example, it is possible to remove by means of CMP polishing approximately 2000 Å from the damaged zone 16, in order to obtain a layer of a thickness varying from 500 Å to 2000 Å and obtain a final roughness of approximately a few A RMS, typically less than 5 Å RMS.

Cleaning may be carried out with for example a 1-5% HF solution (preferentially 1%) for a few minutes (preferentially 1 mm) or with an HF-O₃ solution.

A final GeOI structure, comprising the Ge layer, the insulating layer 30 and the receiving substrate 20, is obtained.

According to the invention, an annealing heat treatment of the structure 40 is used, between approximately 500° C. and 600° C., more specifically between 525° C. and 575° C., more specifically between 525° C. and 550° C., more specifically at approximately 550° C., for 3 hours or less, more specifically for approximately 1 hour, if applicable in an inert atmosphere (argon or nitrogen), in order to restore good electrical and/or optical and crystalline characteristics of the surface layer 15 of germanium, and particularly a good electrical quality at the interface.

In fact, the Applicant noticed that, below 500° C., the germanium layer 15 is not completely reconstructed (see FIGS. 2a to 2c, with the explanation below), and above 600° C., the electrical characteristics deteriorate, for example the electron and hole mobilities have 2 to 5 times lower values than at 550° C. (see FIGS. 3a to 3b, with explanations below).

These results were particularly obtained for insulating layers 30 made of SiO₂ (formed using TEOS), but may also be adapted to other types of insulating materials.

FIGS. 2a to 2c represent respectively three photos taken by means of transmission electron microscopy in layers 15 transferred on a receiving substrate 20, after they have undergone said annealing at respective temperatures of 500° C., 550° C. and 600° C.

In this way, it can be seen clearly that annealing at temperatures between 500° C. and 600° C. makes it possible to restore the defects included in the germanium layer 15, transferred by means of Smart Cut®, at least partially.

FIGS. 3a to 3b respectively present curves obtained according to the Pseudo-MOS method, for different final annealing temperatures (between 500° and 650° C.) on respectively two final structure samples 40 obtained by means of Smart Cut®, showing the variation of the drain-source current (in Amperes) in the layer 15 as a function of the voltage (in Volts) applied at the rear of the substrate 20.

The Pseudo-MOS method is particularly described in “A Review of the Pseudo-MOS Transistor in SOI Wafers: Operation, Parameter Extraction, and Applications” by S. Cristoloveanu et al.; IEEE Transactions on electron devices, vol. 47, No. 5, May 2000).

This method makes it possible to perform a quick evaluation of the electronic properties of a semiconductor-on-insulator wafer, before any production of CMOS components. According to this method, the Ge layer would represent the body of the transistor and the embedded insulator layer 30 would serve as a grid insulator. The thick Si substrate 20 acts as the grid and is polarised by a metal support, inducing a conductive channel at the interface between the layer 15 and the insulator 30. According to the grid polarisation (positive or negative), an inversion or accumulation channel may be activated. The source and the drain are formed by applying controlled pressure probes on the surface of the layer 15.

In this way, using a polarisation of the substrate 20, a good Ge/insulator interface quality will make it possible to prevent as much as possible the load carriers to be trapped at the interface or in intrinsic traps, which will give a good electrical response in the layer 15 to the electrical field applied (i.e. a current will react strongly when a low voltage is applied to the substrate 20).

With reference to FIG. 3a, the temperatures tested for the first sample are 500° C., 550° C., 600° C., 650° C.

With reference to FIG. 3b, the temperatures tested for the second sample are 525° C., 550° C., 575° C., 600° C.

With reference to FIGS. 3a and 3b, it may be noted that results that may be considered as relatively satisfactory were obtained for temperatures between 500° C. and 600° C., somewhat better between 525° C. and 575° C., somewhat better between 525° C. and 550° C. The best result was obtained for a temperature of approximately 525° C., but it may be extrapolated that an optimal result would be obtained for a temperature between 525° C. and 550° C.

In addition, the two tables below present the measurement results (using the Pseudo-MOS method) for the Dit (reflecting the number of traps existing at the interface between Ge and the insulator, generally due to pendant bonds and/or crystalline defects), electron and hole mobility in the layer 15 for different temperatures mentioned above. Table 1 relates to said first sample (FIG. 3a), table 2 relates to said second sample (FIG. 3b).

TABLE 1

| | | Electron | |
|---|---|---|---|
| Temperature | Dit | mobility | Hole mobility |
| 500° C. | 6e13 | 225 m · s⁻² | 430 m · s⁻² |
| 550° C. | 4e12 | 380 m · s⁻² | 280 m · s⁻² |
| 600° C. | 3e13 | 60 m · s⁻² | 160 m · s⁻² |
| 650° C. | 3e13 | 60 m · s⁻² | 50 m · s⁻² |

TABLE 2

| Temper- | | Electron | |
|---|---|---|---|
| ature | Dit | mobility | Hole mobility |
| 525° C. | 7e12 eV⁻¹ × cm⁻² | 310 cm² × V⁻¹ × s⁻¹ | 420 cm² × V⁻¹ × s⁻¹ |
| 550° C. | 7e12 eV⁻¹ × cm⁻² | 310 cm² × V⁻¹ × s⁻¹ | 340 cm² × V⁻¹ × s⁻¹ |
| 575° C. | 1e13 eV⁻¹ × cm⁻² | 120 cm² × V⁻¹ × s⁻¹ | 250 cm² × V⁻¹ × s⁻¹ |
| 600° C. | 4e13 eV⁻¹ × cm⁻² | not measured | 150 cm² × V⁻¹ × s⁻¹ |

These curves and results demonstrate that:
at 500° C.: crystalline reconstruction is still somewhat present, and crystallinity problems and problems at the interfaces remain;
between 525 and 550° C.: the structure is of good quality both in terms of the oxide and the interface.
at temperatures between 550° C. and 600° C., the insulator layer and the interface are of lower quality.
Over 600° C., the insulator layer and the interface are of poor quality.

Once the annealing is performed at the temperatures specified above, the Ge layer 15 is then at least partially restored and displays an improved electrical interface quality.

It should be noted that improved results may be obtained with further improved Dit values if passivation layers as described above are inserted in the structure.

The annealing temperature range will remain the same and will also make it possible to preserve the electrical interface qualities.

If applicable, a deoxidation step at the rear of the substrate 20 is used. It may be performed in liquid phase with protection of the front face or using a single-face machine.

Finally, a final cleaning may be used, for example using HF, and/or ozone.

In the donor substrate 10, in the Ge layer 15 and/or in the receiving substrate 20, other constituents may be added thereto, such as doping agents, or carbon with a carbon concentration in the layer in question substantially less than or equal to 50% or more particularly with a concentration less than or equal to 5%.

Finally, the present invention is not limited to a substrate 10 and 20 made of IV or IV-IV materials described above, but also extends to other types of materials belonging to the II, III, IV, V or VI atomic families and to alloys belonging to the IV-IV, III-V, II-VI atomic families, whereon a Ge layer 15 may be epitaxied (for the donor substrate 10) or bonded (for the receiving substrate 20). In addition, the substrate 10 and/or 20 may comprise intermediate layers made of non-conductor or non-semiconductor materials, such as dielectric materials.

It should be specified that, in the case of alloy materials, the alloys selected may be binary, ternary, quaternary or of a higher degree.

1.-34. (canceled)

35. A method for improving electrical properties of a structure that includes a Ge layer, which method comprises:
bonding a donor substrate that at least includes a thin Ge layer to a receiving substrate to form a structure with the Ge layer having a surface located in proximity to the receiving substrate at a bonding interface;
removing part of the donor substrate but not the thin Ge layer; and
treating the structure at a temperature between 500° C. and 600° C. for not more than 3 hours to improve the electrical properties of the Ge layer or the interface.

36. The method of claim 35, wherein the heat treatment is conducted at a temperature between 525° C. and 575° C. for at least about 1 hour.

37. The method of claim 35, wherein the heat treatment is carried out in an inert atmosphere.

38. The method of claim 35, wherein the thin layer has a thickness between approximately 50 and approximately 200 nanometers and the receiving substrate is made of Si.

39. The method of claim 35, which also comprises forming a passivation layer on the Ge layer prior to bonding.

40. The method of claim 39, wherein the passivation layer is GeOxNy, and is formed by one or combinations of the following techniques:
oxidizing the surface of the Ge layer to form a Ge oxide, followed by nitriding of the Ge oxide;
nitriding the surface of the Ge layer to form a Ge nitride oxide, followed by oxidizing of the Ge nitride;
heat treating the surface of the Ge layer using nitrogen and oxygen; or
plasma treating the surface of the Ge layer with NH3, N2, O2 or a mixture of N2+O2.

41. The method of claim 39, which also comprises depositing on the passivation layer prior to bonding an interfacial layer of a material that improves the optical/or morphological properties at the interface.

42. The method of claim 35, which further comprises depositing on the surface of the Ge layer prior to bonding an interfacial layer of a material intended to improve the electrical or optical properties at the interface.

43. The method of claim 42, wherein the interfacial layer is made of epitaxied Si, a high dielectric constant material, HfO2, or AlN.

44. The method of claim 35, which further comprises prior to bonding forming a layer of electrical insulator at a temperature of 500 to 600° C. or less on one of the donor substrate or the receiving substrate.

45. The method of claim 44, wherein the insulating layer is an oxide, a nitride or an oxynitride.

46. The method of claim 45, wherein the insulating layer is SiO2, and is formed by:
vapor phase deposition using a silane;
vapor phase deposition using TEOS;
thermal oxidation of the receiving substrate when the receiving substrate is made of silicon; and
thermal oxidation of a layer of Si that is previously deposited on the surface of the Ge layer.

47. The method of claim 35, which further comprises prior to bonding implanting atomic species into the donor substrate to form a weakened zone at a depth that corresponds to the thickness of the Ge layer; and, after bonding, applying energy to remove the remaining part of the donor substrate at the weakened zone.

48. The method of claim 47, which further comprises conducting a finishing step on the Ge layer to improve the thickness homogeneity and surface roughness after removing the remaining part of the donor substrate.

49. The method of claim 47, wherein the finishing step is applied to impart a surface roughness to the Ge layer of between approximately 1 and approximately 5 Angstroms RMS.

50. The method of claim 35, wherein the donor substrate is a bulk Ge substrate or a composite structure comprising the thin Ge layer on the surface.

51. In a structure that includes a donor substrate that at least includes a thin Ge layer bonded to a receiving substrate to form a structure with the Ge layer having a surface located in proximity to the receiving substrate at a bonding interface; the improvement which comprises improving electrical properties by treating the structure at a temperature between 500° C. and 600° C. for not more than 3 hours to improve the electrical properties of the Ge layer or the interface.

52. A Ge-on-insulator structure comprising a Ge layer bonded with a substrate via an SiO2 bonding layer having a density of Ge/SiO2 interface traps (or “Dit”) that are less than or equal to 5e13 eV-1.cm-2.

53. The structure of claim 52, wherein the Dit is less than or equal to 7e12 eV-1.cm-2 to 4e13 eV-1.cm-2.

54. The structure of claim 52, further comprising a passivation or interface layer between the Ge layer and the SiO2 layer.
